(19) United States
(12) Patent Application Publication
(10) Pub. No.: US 2009/0057867 A1
(43) Pub. Date: Mar. 5, 2009

(54) Integrated Circuit Package with Passive Component

(76) Inventor: Vincent Hool, Pleasanton, CA (US)

Correspondence Address: MORGAN, LEWIS & BOCKIUS LLP, 1111 PENNSYLVANIA AVENUE, WASHINGTON, DC, 20004, US

(21) Appl. No.: 11/847,470

(22) Filed: Aug. 30, 2007

(51) Int. Cl. H01L 23/52; H01L 21/56

(52) U.S. Cl. 257/690; 438/127; 257/E23.141; 257/E21.502

(57) ABSTRACT

The present invention comprises a substrate, an integrated circuit mounted on the substrate, a passive component such as a capacitor mounted on the integrated circuit, and an encapsulation enclosing the integrated circuit and the passive component. The integrated circuit can be mounted in a flip-chip configuration with its active side facing the substrate and the passive component mounted on its backside or with its active side up with its backside on the substrate and the passive component mounted on the active side of the integrated circuit.

### FIELD OF THE INVENTION

This relates to an implementation of a capacitor or other passive component in an integrated circuit package.

### BACKGROUND OF THE INVENTION

The switching of input/output (I/O) circuits for semiconductor integrated circuits requires large amounts of electric current. The electric charge for this current is conventionally stored in decoupling capacitors on the printed circuit board on which the integrated circuit package is mounted, on package capacitors or on capacitors formed in the integrated circuit itself. This arrangement is illustrated schematically in FIG. 1 where a capacitor 10 is connected between power (Vcc) and ground (Vss) lines supplying an integrated circuit 20. An example of the physical implementation of the circuit of FIG. 1 is in a package capacitor such as shown in FIG. 2. This implementation comprises a package substrate 210, an integrated circuit 220 mounted in a flip-chip configuration on package substrate 210, a capacitor 240 mounted on the package substrate 210, and a cover 260 that is secured to substrate 210 and encloses integrated circuit 220 and package capacitor 240. Further details concerning conventional decoupling capacitors may be found in R. Tummala, Fundamentals of Microsystems Packaging, pp. 122-131 (McGraw-Hill 2001), which is incorporated herein by reference.

None of these prior art charge storage arrangements is ideal. While a capacitor formed in the integrated circuit has the advantage that it is located as close to the integrated circuit as possible, this closeness comes at the price of the space on the integrated circuit that it occupies. This space is often some of the most expensive space in the world. As a result, an on-chip capacitor is rarely preferred as a source of switching current.

Other locations for the capacitor(s) are farther away which results in greater signal delay and slower switching speeds for the I/O circuits. While a capacitor mounted alongside the integrated circuit is relatively close to the integrated circuit, it has the disadvantage that it requires the size of the integrated circuit package to be expanded to accommodate the capacitor. And while a capacitor mounted at some convenient location on the printed circuit board avoids space problems, it has the disadvantage of being a considerable distance from the integrated circuit.

### SUMMARY OF THE PRESENT INVENTION

The present invention avoids the problems of the prior art by mounting a capacitor on top of the integrated circuit within the integrated circuit package. As a result, the package comprises a substrate, an integrated circuit mounted on the substrate, a capacitor mounted on the integrated circuit and a cover secured to the substrate and enclosing the integrated circuit and the capacitor.

The integrated circuit can be mounted in a flip-chip configuration with its active side facing the substrate and the capacitor mounted on its backside or with its active side up with its backside on the substrate and the capacitor mounted on the active side of the integrated circuit.

In alternative embodiments of the invention, other passive components may be mounted in place of or in addition to the capacitor on top of the integrated circuit within the integrated circuit package.

### BRIEF DESCRIPTION OF THE DRAWINGS

These and other objects and advantages of the present invention will be apparent to those of ordinary skill in the art in view of the following detailed description in which:

FIG. 1 is a schematic illustration of a prior art circuit for powering an integrated circuit;

FIG. 2 is an illustration of a prior art semiconductor integrated circuit package;

FIG. 3 is an illustration of a first embodiment of the invention;

FIG. 4 is an illustration of a second embodiment of the invention; and

FIGS. 5 and 6 depict alternative details of portions of FIG. 3.

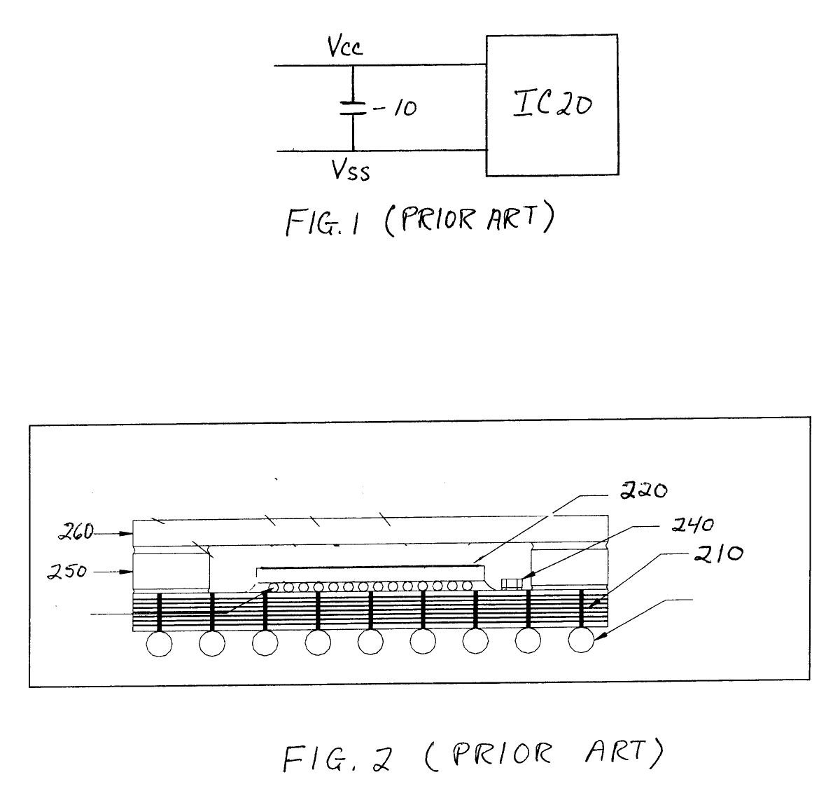

### DETAILED DESCRIPTION

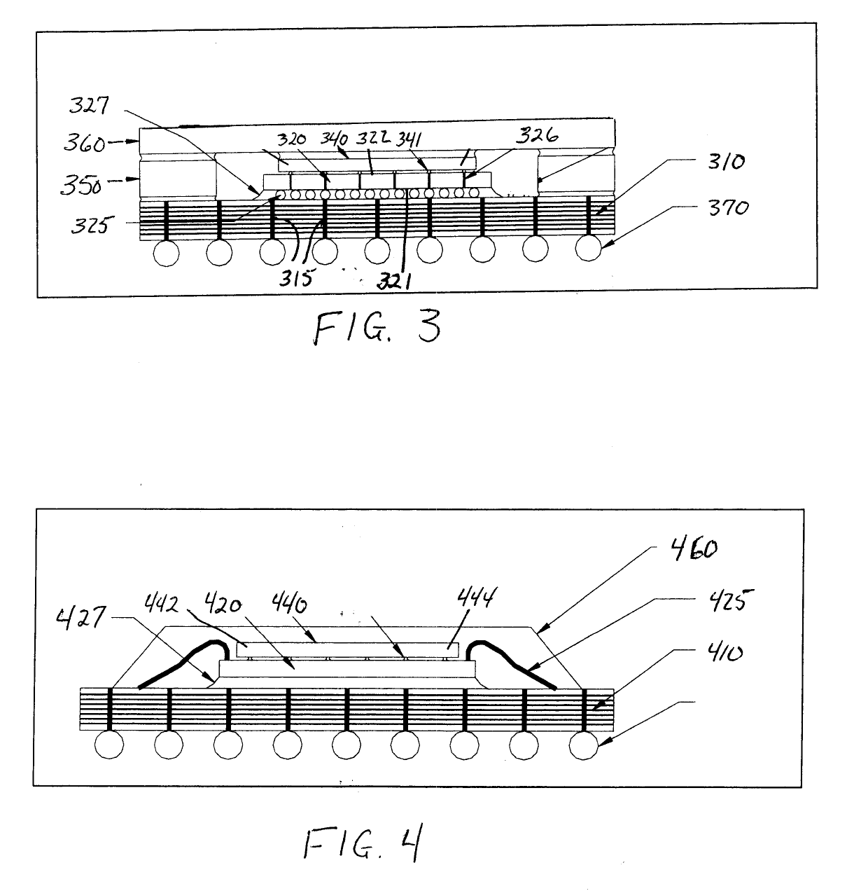

FIG. 3 depicts an illustrative embodiment of an integrated circuit package 300 of the present invention. Package 300 comprises a package substrate 310, an integrated circuit 320 mounted on substrate 310, a capacitor 340 mounted on integrated circuit 320, a stiffener 350 that is secured to the periphery of substrate 310 and a cover 360 that is secured to stiffener 350 and encloses integrated circuit 320 and capacitor 340.

Substrate 310 is a multi-layer planar structure of insulating materials and conductors. Typically, the insulating materials are bismaleimide triazine (BT) or FR5 epoxy/glass laminate and the conductors are copper. A pattern of electrical interconnects 315 is defined on the interior surface of substrate 310 and extends through the substrate to provide power, ground and I/O signal connections to the outside of the substrate. The electrical interconnects may be a conventional lead frame or an array of electrically conductive horizontal layers and vertical vias extending between ball grid array (BGA) balls or pins 325 and BGA balls or pins 370 as is known in the art and disclosed, for example, in my U.S. Pat. No. 6,864,565, which is incorporated herein by reference. In the embodiment shown in FIG. 3, electrical connections to package 300 are made through BGA balls or pins 370 mounted on copper pads (not shown) on the exterior of substrate 310.

Integrated circuit 320 is a planar structure of a semiconductor material, typically silicon, in which a plurality of active devices are defined on one side of the structure along with one or more layers of interconnects. This side of the structure will be referred to as the active side 321 and the opposite side will be referred to as the backside 322. An integrated circuit may be mounted on a substrate either right side up with its backside facing the substrate; or upside down with its active side facing the substrate. The right side up mounting is often referred to as the wire bond mounting; and the upside down mounting is often referred to as the flip-chip configuration. In the embodiment shown in FIG. 3, integrated circuit 320 is mounted upside down in the flip-chip configuration. In this configuration, electrical connections between the integrated circuit 320 and connection patterns on the substrate are made through solder balls (or solder bumps) 325 between electrical interconnects 315 on the substrate and under bump metallization (UBM) on the integrated circuit. Integrated circuit 320 is mechanically attached to the substrate by the solder balls (or solder bumps) and by a conventional underfill adhesive 327.

Electrical connections 326 extend through integrated circuit 320 from active side 321 to backside 322. Preferably, electrical connections 326 are through-silicon-vias (TSV) made of copper, aluminum or doped polysilicon.

Capacitor 340 is a planar structure conventionally formed by a plurality of electrically conductive layers separated by an insulating member. Typically, every other conductive layer is connected to at least one electrode and the remaining conductive layers are connected to at least a second electrode. Preferably, the capacitor is a standard ceramic capacitor having a length and width that are approximately coextensive with the length and width of integrated circuit 320. Capacitor 340 is electrically connected to the power and ground interconnects to the integrated circuit by at least two of the electrical connections 326 that extend through the integrated circuit and connect to the capacitor electrodes via solder joints 341. Capacitor 340 is mechanically attached to the integrated circuit by the solder joints and by a conventional adhesive.

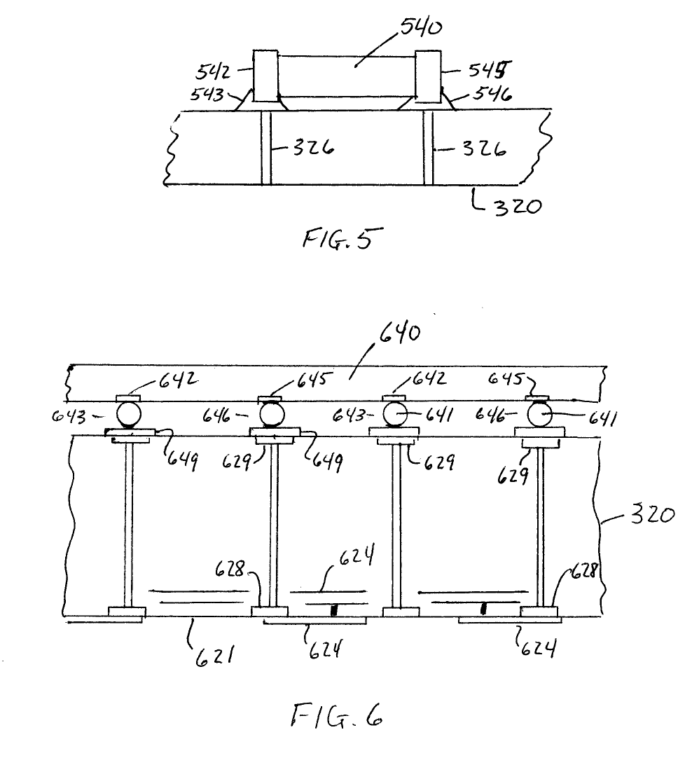

FIGS. 5 and 6 are enlarged views of alternative versions of capacitor 340 and its connection to electrical connections 326. In FIG. 5, a capacitor 540 has two electrodes 542, 545 spaced apart on an external surface of the capacitor. Electrode 542 illustratively is connected to power, V_{CC}, through a solder joint 543 at the top of one of the through-silicon-via (TSV) electrical connections 326. Electrode 545 illustratively is connected to ground, V_{SS}, through a second solder joint 546 at the top of a second TSV electrical connection 326. Further details of the electrical connections are shown in FIG. 6.

The structure of FIG. 6 is similar but depicts a capacitor 640 with several electrodes 642, each of which is connected to power, V_{CC}, and several electrodes 645, each of which is connected to ground, V_{SS}, and illustrates further details of integrated circuit 320. In particular, capacitor 640 has two sets 642, 645 of electrodes spaced apart on an external surface of the capacitor. Each of the electrodes in set 642 illustratively is connected to power, Vcc, through a solder joint 643 at the top of one of the TSV electrical connections 326. Each of the electrodes in set 645 is connected to ground, V_{SS}, through a different solder joint 646 at the top of a different one of the TSV electrical connections 326.

Further details of a typical electrical connection are illustrated in FIG. 6. Each TSV electrical connection 326 extends through integrated circuit 320 to the active side 621 of the circuit where it typically is connected to one or more conductive layers 624, lying on or near the surface of the integrated circuit. Each electrical connection 326 terminates in a pad 628 on the active side 321 and a pad 629 on the backside 322. A solder bump pad 649 is formed on pad 629. To make electrical connections between TSV connections 326 and the electrodes 642, 645 of capacitor 640, solder bumps 641 are deposited on the solder bump pads and the solder balls are then heated to form solder joints that connect each of the TSV connectors to one of the electrodes of the capacitor.

Stiffener 350 is a conventional element that extends around the periphery of the substrate and provides added strength to resist warppage. Stiffener 350 is bonded to the substrate by a conventional adhesive. Cover 360 is a planar member that is secured to stiffener 350 and encloses integrated circuit 320 and capacitor 340. Optionally, cover 360 may also serve as a heat sink. For further strength in the package, cover 360 may also be secured to capacitor 340 by a conventional adhesive 347 as shown in FIG. 3.

FIG. 4 depicts a second embodiment of an integrated circuit package 400 of the present invention. Package 400 comprises a package substrate 410, an integrated circuit 420 mounted on substrate 410, and a capacitor 440 mounted on integrated circuit 420. Substrate 410, integrated circuit 420 and capacitor 440 are similar to substrate 310, integrated circuit 320 and capacitor 340 of FIG. 3 but integrated circuit 420 is mounted right side up on substrate 410. When mounted right side up, electrical connections between the integrated circuit and connection patterns on the substrate are typically made by wire bonds 425 running between the connection patterns and bonding pads on the upper surface of the integrated circuit. Integrated circuit 420 is secured to substrate 410 by a die attach adhesive 427.

Capacitor 440 is a planar structure conventionally formed by a plurality of electrically conductive members separated by an insulating member. Capacitor 440 has at least two electrodes that are electrically connected to the power and ground leads of the integrated circuit. Again, one electrode or set of electrodes on capacitor 440 is connected to power, V_{CC}, and another electrode or set of electrodes is connected to ground V_{SS}. Again, the connections are made through solder joints; but in this case the solder joints are formed on solder bump pads on the active side of integrated circuit 420. Capacitor 440 is secured to integrated circuit 420 by the electrical connections and possibly an underfill adhesive.

In the embodiment of FIG. 4, integrated circuit 420 and capacitor 440 are encapsulated in an overmold 460.

As will be apparent to those skilled in the art, numerous variations may be made within the spirit and scope of the invention. As noted above, other passive components may be mounted on the integrated circuit in place of, or in addition to, a capacitor.

1. A semiconductor chip package comprising:
a substrate;
a semiconductor integrated circuit mounted on the substrate;
a passive component mounted on the semiconductor integrated circuit and electrically connected thereto; and
an encapsulation mounted on the substrate and enclosing the semiconductor integrated circuit and the passive component.

2. The semiconductor chip package of claim 1 wherein the passive component is substantially planar.

3. The semiconductor chip package of claim 1 wherein the passive component is substantially coextensive with the semiconductor integrated circuit on which it is mounted.

4. The semiconductor chip package of claim 1 wherein the integrated circuit has an active side and a backside, the integrated circuit is mounted so that the active side faces the substrate and the passive component is mounted on the backside of the integrated circuit.

5. The semiconductor chip package of claim 4 wherein the integrated circuit comprises a plurality of through-silicon-vias that connect to electrodes on the passive component.

6. The semiconductor chip package of claim 1 wherein the integrated circuit has an active side and a backside, the integrated circuit is mounted so that the backside faces the substrate and the passive component is mounted on the active side of the integrated circuit.

7. The semiconductor chip package of claim 1 wherein the passive component is a capacitor.

8. The semiconductor chip package of claim 1 wherein the encapsulation comprises an overmold.

9. The semiconductor chip package of claim 1 wherein the encapsulation comprises a stiffener mounted on the substrate and a cover mounted on the stiffener.

10. The semiconductor chip package of claim 9 wherein the stiffener extends around the periphery of the substrate.

11. A semiconductor chip package comprising:
a substrate;
a semiconductor integrated circuit flip-chip mounted on the substrate, said integrated circuit having a plurality of electrically conductive through-silicon-via therethrough;
a capacitor mounted on the semiconductor integrated circuit and electrically connected thereto by the plurality of through-silicon-vias; and
an encapsulation mounted on the substrate and enclosing the semiconductor integrated circuit and the capacitor.

12. The semiconductor chip package of claim 11 wherein the capacitor is substantially planar.

13. The semiconductor chip package of claim 11 wherein the capacitor is substantially coextensive with the semiconductor integrated circuit on which it is mounted.

14. The semiconductor chip package of claim 11 wherein the encapsulation comprises an overmold.

15. The semiconductor chip package of claim 11 wherein the encapsulation comprises a stiffener mounted on the substrate and a cover mounted on the stiffener.

16. A semiconductor chip package comprising:
a substrate;
a semiconductor integrated circuit wire-bond mounted on the substrate;
a capacitor mounted on the semiconductor integrated circuit and electrically connected thereto; and
an encapsulation mounted on the substrate and enclosing the semiconductor integrated circuit and the capacitor.

17. The semiconductor chip package of claim 16 wherein the capacitor is substantially planar.

18. The semiconductor chip package of claim 16 wherein the capacitor is substantially coextensive with the semiconductor integrated circuit on which it is mounted.

19. The semiconductor chip package of claim 16 wherein the encapsulation comprises an overmold.

20. The semiconductor chip package of claim 16 wherein the encapsulation comprises a stiffener mounted on the substrate and a cover mounted on the stiffener.

21. A method of forming a semiconductor package comprising:
mounting a semiconductor integrated circuit on a substrate;
mounting a passive component on the semiconductor integrated circuit and electrically connecting the passive component to the semiconductor integrated circuit; and
mounting on the substrate an encapsulation that encloses the semiconductor integrated circuit and the passive component.
